(19) United States
(12) Patent Application Publication
(10) Pub. No.: US 2026/0160837 A1
(43) Pub. Date: Jun. 11, 2026

(54) MAGNETIC SENSOR AND MANUFACTURING METHOD FOR THE SAME

(71) Applicant: TDK Corporation, Tokyo (JP)

(72) Inventors: Kazuya WATANABE, Tokyo (JP); Hiraku HIRABAYASHI, Tokyo (JP); Norikazu OTA, Tokyo (JP)

(73) Assignee: TDK Corporation, Tokyo (JP)

(21) Appl. No.: 19/179,083

(22) Filed: Apr. 15, 2025

(30) Foreign Application Priority Data
May 10, 2024 (JP) 2024-077151

(51) Int. Cl. G01R 33/09

(52) U.S. Cl. CPC G01R 33/098; G01R 33/093

(57) ABSTRACT

A magnetic sensor includes: a support member including a first inclined surface and a second inclined surface that are inclined with respect to a reference plane and oriented in directions different from each other; a first MR element disposed on the first inclined surface; a second MR element disposed on the second inclined surface; and a first electrode that connects the first MR element and the second MR element, the first electrode including a part overlapping with a center of gravity of the first MR element and a center of gravity of the second MR element, when viewed in a direction perpendicular to the reference plane.

### CROSS REFERENCE TO RELATED APPLICATIONS

This application claims the benefit of Japanese Priority Patent Application No. 2024-77151 filed on May 10, 2024, the entire contents of which are incorporated herein by reference.

### BACKGROUND

The disclosure relates to a magnetic sensor including a magnetoresistive element disposed on an inclined surface, and a manufacturing method for the magnetic sensor.

In recent years, magnetic sensors have been used for a variety of applications. Examples of known magnetic sensors include one that uses a spin-valve magnetoresistive element provided on a substrate. The spin-valve magnetoresistive element includes a magnetization pinned layer, a magnetization direction of which is fixed, a free layer, a magnetization direction of which is variable depending on the direction of a magnetic field to be applied, and a gap layer disposed between the magnetization pinned layer and the free layer. In many cases, a spin-valve magnetoresistive element provided on a substrate is configured to have sensitivity to a magnetic field in a direction parallel to the surface of the substrate. Such a magnetoresistive element is thus suitable to detect a magnetic field whose direction changes within a plane parallel to the surface of the substrate.

On the other hand, a system including a magnetic sensor may be intended to detect a magnetic field containing a component in a direction perpendicular to a surface of a substrate by using a magnetoresistive element provided on the substrate. In such a case, the magnetic field containing the component in a direction perpendicular to the surface of the substrate can be detected by disposing the magnetoresistive element on an inclined surface formed on the substrate. For example, JP 2006-261401A discloses a magnetic sensor including a Z-axis sensor disposed on inclined surfaces of a plurality of protrusion portions on a substrate. The giant magnetoresistive elements that constitute the Z-axis sensor include magnetosensitive portions provided along the longitudinal direction of the slopes.

An effective way of suppressing the influence of noise is to increase the number of magnetoresistive elements. As in the magnetic sensor disclosed in JP 2006-261401A, the magnetic sensor configured such that the magnetoresistive elements are provided on the inclined surfaces is capable of increasing sensitivity of the magnetic sensor by providing a plurality of magnetoresistive elements on one inclined surface. Here, it is supposed that a plurality of magnetoresistive elements provided on one inclined surface are connected in series by wiring. In such a case, the width of the wiring becomes smaller than the width of the inclined surface.

Incidentally, with miniaturization of devices to which magnetic sensors are mounted, there has also been a demand for miniaturization of the magnetic sensors. Trying to miniaturize the magnetic sensor would result in a reduction of a width of a wiring for connecting a plurality of magnetoresistive elements. As a result, a ratio of a resistance of the wiring to a resistance of the magnetoresistive elements becomes large, which causes a problem of a drop in the sensitivity of the magnetic sensor. This problem is significant when a plurality of magnetoresistive elements connected in series are disposed on one inclined surface.

### SUMMARY

A magnetic sensor according to one embodiment of the disclosure includes: a support member including a first inclined surface and a second inclined surface that are inclined with respect to a reference plane and oriented in directions different from each other; a first magnetoresistive element disposed on the first inclined surface; a second magnetoresistive element disposed on the second inclined surface; and a first electrode configured to connect the first magnetoresistive element and the second magnetoresistive element, the first electrode including a part overlapping with a center of gravity of the first magnetoresistive element and a center of gravity of the second magnetoresistive element, when viewed in a first direction perpendicular to the reference plane.

A manufacturing method for the magnetic sensor according to one embodiment of the disclosure includes forming a first magnetoresistive element and a second magnetoresistive element. Each of the first magnetoresistive element and the second magnetoresistive element includes a magnetization pinned layer, a magnetization direction of the magnetization pinned layer being fixed, and a free layer, a magnetization direction of the free layer being variable depending on a magnetic field to be applied. The forming the first magnetoresistive element and the second magnetoresistive element includes: forming a stacked film including an initial magnetization pinned layer, which is to later become the magnetization pinned layer, and the free layer; and fixing a magnetization direction of the initial magnetization pinned layer by using laser light and an external magnetic field. The fixing includes a first step of fixing the magnetization direction of the initial magnetization pinned layer in a part, which is to later become the first magnetoresistive element, of the stacked film, and includes, after the first step, a second step of fixing the magnetization direction of the initial magnetization pinned layer in a part, which is to later become the second magnetoresistive element, of the stacked film.

Other and further objects, features, and advantages of the disclosure will appear more fully from the following description.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a plan view showing a magnetic sensor according to a first example embodiment of the disclosure.

FIG. 2 is a circuit diagram showing a circuit configuration of the magnetic sensor according to the first example embodiment of the disclosure.

FIG. 3 is a plan view showing a part of the magnetic sensor according to the first example embodiment of the disclosure.

FIG. 4 is a sectional view showing a part of the magnetic sensor according to the first example embodiment of the disclosure.

FIG. 5 is an explanatory diagram schematically showing a resistor section in the first example embodiment of the disclosure.

FIG. 6 is a plan view showing a plurality of magnetoresistive elements, a plurality of lower electrodes, and a plurality of upper electrodes in the first example embodiment of the disclosure.

FIG. 7 is a perspective view showing the magnetoresistive element in the first example embodiment of the disclosure.

FIG. 8 is a perspective view showing a magnetic sensor system in the first example embodiment of the disclosure.

FIG. 9 is a sectional view showing a part of a magnetic sensor according to a second example embodiment of the disclosure.

FIG. 10 is a plan view showing a plurality of magnetoresistive elements, a plurality of lower electrodes, and a plurality of upper electrodes in the second example embodiment of the disclosure.

### DETAILED DESCRIPTION

An object of the disclosure is to provide a magnetic sensor that can reduce a resistance of a wiring that connects magnetoresistive elements.

In the following, some example embodiments and modification examples of the disclosure will be described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions. Note that the description is given in the following order.

### First Example Embodiment

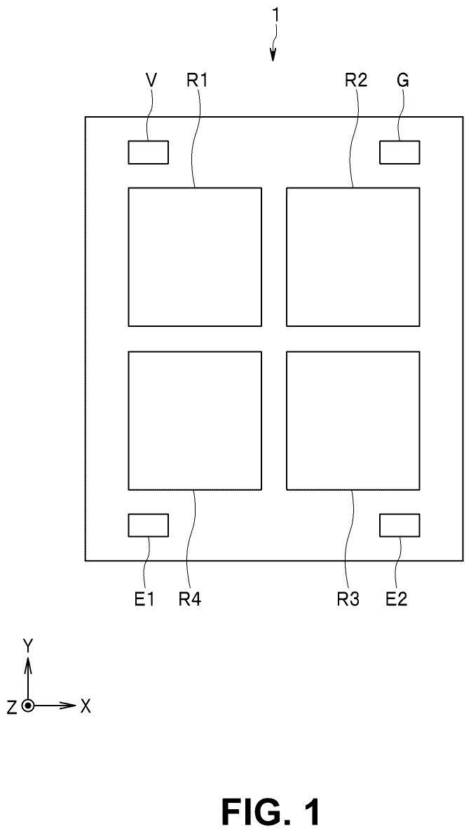

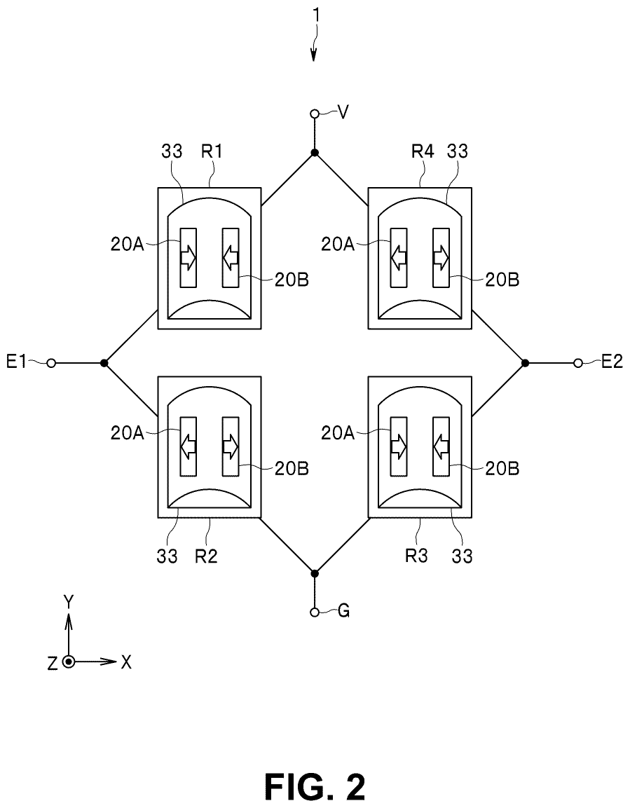

First, a schematic configuration of a magnetic sensor according to a first example embodiment of the disclosure will be described with reference to FIG. 1 and FIG. 2. FIG. 1 is a plan view showing a magnetic sensor 1 according to the example embodiment. FIG. 2 is a circuit diagram showing a circuit configuration of the magnetic sensor 1 according to the example embodiment.

The magnetic sensor 1 according to the example embodiment includes four resistor sections R1, R2, R3, and R4, a power supply terminal V, a ground terminal G, a first output terminal E1, and a second output terminal E2. The resistor sections R1 to R4 each include a plurality of magnetoresistive elements (hereinafter, referred to as MR elements). The resistor sections R1 to R4, the power supply terminal V, the ground terminal G, and the first and second output terminals E1, E2 are disposed on one substrate.

As shown in FIG. 2, the resistor section R1 is provided between the power supply terminal V and the first output terminal E1 in a circuit configuration. The resistor section R2 is provided between the ground terminal G and the first output terminal E1 in the circuit configuration. The resistor section R3 is provided between the ground terminal G and the second output terminal E2 in the circuit configuration. The resistor section R4 is provided between the power supply terminal V and the second output terminal E2 in the circuit configuration. Note that, in the present application, the expression “in the (a) circuit configuration” is used to indicate an arrangement in a circuit diagram, not an arrangement in a physical configuration.

A voltage or current of a specified magnitude is applied to the power supply terminal V. The ground terminal G is connected to the ground.

Here, as shown in FIG. 1, an X direction, a Y direction, and a Z direction are defined. The X direction, the Y direction, and the Z direction are orthogonal to one another. The opposite directions to the X, Y, and Z directions will be expressed as −X, −Y, and −Z directions, respectively. In the example embodiment, in particular, the Z direction refers to a direction perpendicular to a surface of the substrate on which the resistor sections R1 to R4, the power supply terminal V, the ground terminal G, and the first and second output terminals E1, E2 are provided.

As used herein, the term “above” refers to positions located forward of a reference position in the Z direction, and “below” refers to positions located on a side of the reference position opposite to “above”. For each component of the magnetic sensor 1, the term “top surface” refers to a surface of the component lying at the end thereof in the Z direction, and “bottom surface” refers to a surface of the component lying at the end thereof in the −Z direction. The expression “when viewed in a specified direction (e.g., the Z direction)” means that an object is viewed from a position away in the specified direction or in one direction parallel to the specified direction.

FIG. 1 shows an example of the arrangement of the resistor sections R1 to R4. In this example, the resistor sections R1 and R2 are arranged in a direction parallel to the X direction. The resistor section R2 is located forward of the resistor section R1 in the X direction.

The resistor sections R3 and R4 are arranged in a direction parallel to the X direction. The resistor section R4 is located forward of the resistor section R3 in the −X direction. The resistor section R3 is located forward of the resistor section R2 in the −Y direction. The resistor section R4 is located forward of the resistor section R1 in the −Y direction.

Note that the arrangement of the resistor sections R1 to R4 is not limited to the example shown in FIG. 1. For example, the resistor sections R1 to R4 may be disposed in a specified order in the direction parallel to the X direction or in a direction parallel to the Y direction.

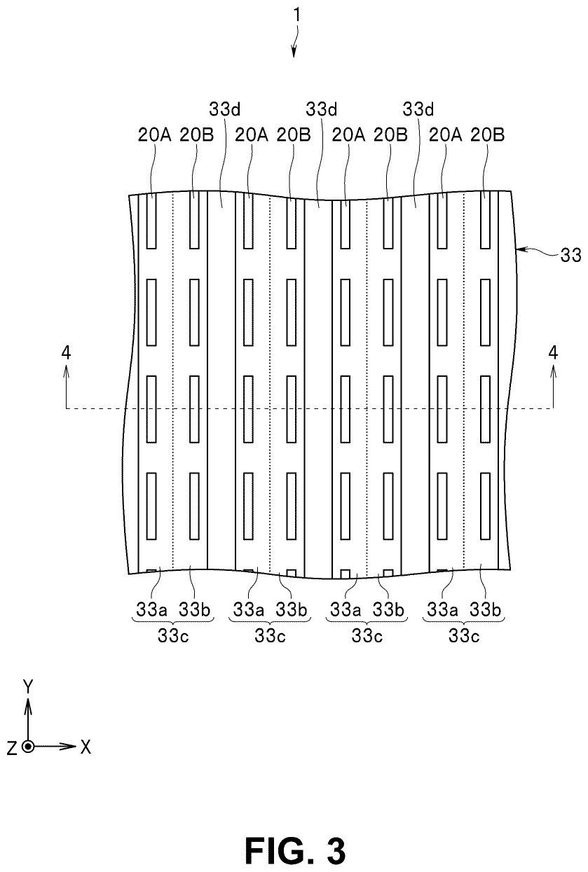

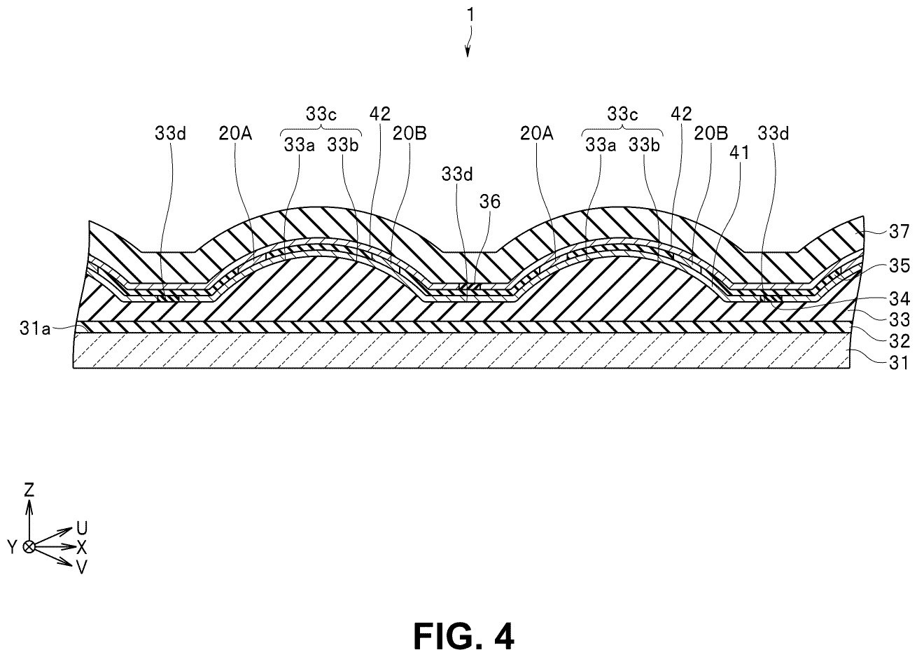

Next, a specific structure of the magnetic sensor 1 will be described in detail with reference to FIG. 3 and FIG. 4. FIG. 3 is a plan view showing a part of the magnetic sensor 1. FIG. 4 shows a part of the cross section at the position indicated by the line 4-4 in FIG. 3.

The magnetic sensor 1 further includes a wiring 40. The resistor section R1 is electrically connected to the power supply terminal V and the first output terminal E1 by the wiring 40. The resistor section R2 is electrically connected to the ground terminal G and the first output terminal E1 by the wiring 40. The resistor section R3 is electrically connected to the ground terminal G and the second output terminal E2 by the wiring 40. The resistor section R4 is electrically connected to the power supply terminal V and the second output terminal E2 by the wiring 40.

Each of the resistor sections R1 to R4 includes a plurality of first MR elements 20A, a plurality of second MR elements 20B, and a plurality of lower electrodes 41 and a plurality of upper electrodes 42, each connecting the plurality of first MR elements 20A and the plurality of second MR elements 20B. Since the resistor sections R1 to R4 are components of the magnetic sensor 1, it can be said that the magnetic sensor 1 includes the plurality of first MR elements 20A, the plurality of second MR elements 20B, the plurality of lower electrodes 41, and the plurality of upper electrodes 42. The lower electrodes 41 and the upper electrodes 42 constitute a part of the wiring 40. Hereinafter, any given MR element will be denoted by the reference numeral 20.

In each of the resistor sections R1 to R4, the plurality of first MR elements 20A and the plurality of second MR elements 20B are electrically connected by the plurality of lower electrodes 41 and the plurality of upper electrodes 42. The connecting form of the plurality of first MR elements 20A and the plurality of second MR elements 20B will be described in detail later.

Here, as shown in FIG. 4, a U direction and a V direction are defined as follows. The U direction is a direction rotated from the X direction to the Z direction. The V direction is a direction rotated from the X direction to the −Z direction. In the example embodiment, in particular, the U direction is set to a direction rotated from the X direction to the Z direction by α, and the V direction is set to a direction rotated from the X direction to the −Z direction by α. Note that α is an angle greater than 0° and smaller than 90°. A −U direction refers to a direction opposite to the U direction, and a −V direction refers to a direction opposite to the V direction. The U direction and V direction both are orthogonal to the Y direction.

As shown in FIG. 4, the magnetic sensor 1 includes a substrate 31 having a top surface 31a, and insulating layers 32, 33, 34, 35, 36, and 37. The top surface 31a of the substrate 31 is parallel to the XY plane. The top surface 31a of the substrate 31 corresponds to the “reference plane” in the disclosure. The Z direction is also a direction perpendicular to the top surface 31a of the substrate 31.

The insulating layers 32 and 33 are stacked on the substrate 31 in this order. The plurality of lower electrodes 41 are disposed on the insulating layer 33. The insulating layer 34 is disposed around the plurality of lower electrodes 41 on the insulating layer 33. The plurality of first MR elements 20A and the plurality of second MR elements 20B are disposed on the plurality of lower electrodes 41. The insulating layer 35 is disposed around the plurality of first MR elements 20A and the plurality of second MR elements 20B, on the plurality of lower electrodes 41 and the insulating layer 34. The plurality of upper electrodes 42 are disposed on the plurality of first MR elements 20A, the plurality of second MR elements 20B, and the insulating layer 35. The insulating layer 36 is disposed around the plurality of upper electrodes 42 on the insulating layer 35. The insulating layer 37 is disposed on the plurality of upper electrodes 42 and the insulating layer 36.

The magnetic sensor 1 includes a support member supporting the plurality of first MR elements 20A and the plurality of second MR elements 20B. The support member includes at least one inclined surface inclined with respect to the top surface 31a of the substrate 31. In the example embodiment, in particular, the support member is configured of the insulating layer 33. Note that FIG. 3 shows the insulating layer 33, the plurality of first MR elements 20A, and the plurality of second MR elements 20B, among the components of the magnetic sensor 1.

The insulating layer 33 includes a plurality of protruding surfaces 33c each protruding in a direction (the Z direction) away from the top surface 31a of the substrate 31. Each of the plurality of protruding surfaces 33c extends in a direction parallel to the Y direction. The overall shape of the protruding surface 33c is a semi-cylindrical curved surface formed by moving the curved shape (arch shape) of the protruding surface 33c shown in FIG. 4 along the direction parallel to the Y direction. The plurality of protruding surfaces 33c are arranged in the direction parallel to the X direction at certain intervals.

Each of the plurality of protruding surfaces 33c includes an upper end portion farthest from the top surface 31a of the substrate 31. In the example embodiment, the upper end portion of each of the plurality of protruding surfaces 33c extends in the direction parallel to the Y direction. Herein, focus is placed on a given protruding surface 33c of the plurality of protruding surfaces 33c. The protruding surface 33c includes inclined surfaces 33a and 33b oriented in directions different from each other. The inclined surface 33a refers to the part of the protruding surface 33c on the −X direction side with respect to the upper end portion of the protruding surface 33c. The inclined surface 33b refers to the part of the protruding surface 33c on the X direction side with respect to the upper end portion of the protruding surface 33c. In FIG. 3, the boundary between the inclined surface 33a and the inclined surface 33b is shown by a dotted line.

The upper end portion of the protruding surface 33c may be the boundary between the inclined surface 33a and the inclined surface 33b. In such a case, the dotted line shown in FIG. 3 represents the upper end portion of the protruding surface 33c.

The top surface 31a of the substrate 31 is parallel to the XY plane. The inclined surface 33a and the inclined surface 33b are each inclined with respect to the top surface 31a of the substrate 31, i.e., the XY plane. In a cross section perpendicular to the top surface 31a of the substrate 31, the distance between the inclined surface 33a and the inclined surface 33b decreases with increasing distance from the top surface 31a of the substrate 31.

In the example embodiment, since the plurality of protruding surfaces 33c are present, also a plurality of inclined surfaces 33a and a plurality of inclined surfaces 33b are present. The insulating layer 33 includes the plurality of inclined surfaces 33a and the plurality of inclined surfaces 33b.

The insulating layer 33 may further include a non-protruding surface 33d present around the plurality of protruding surfaces 33c. The non-protruding surface 33d may be a surface parallel to the top surface 31a of the substrate 31, or may not be a surface parallel to the top surface 31a of the substrate 31. In the example embodiment, the non-protruding surface 33d is a surface parallel to the top surface 31a of the substrate 31, that is, a plane parallel to the XY plane. Each of the plurality of protruding surfaces 33c protrudes from the non-protruding surface 33d in the Z direction. In the example embodiment, the plurality of protruding surfaces 33c are located at intervals. The non-protruding surface 33d is thus present between the two protruding surfaces 33c adjoining in the X direction.

The plurality of lower electrodes 41 are disposed on the plurality of inclined surface 33a and the plurality of inclined surfaces 33b. As described above, since the

inclined surfaces 33a and the inclined surfaces 33b are each inclined with respect to the top surface 31a of the substrate 31, that is, the XY plane, each of the top surfaces of the plurality of lower electrodes 41 is also inclined with respect to the XY plane. Thus, it can be said that the plurality of first MR elements 20A and the plurality of second MR elements 20B are disposed on the inclined surfaces inclined with respect to the XY plane. The insulating layer 33 is a member for supporting each of the plurality of first MR elements 20A and the plurality of second MR elements 20B so as to allow such MR elements to be inclined with respect to the XY plane.

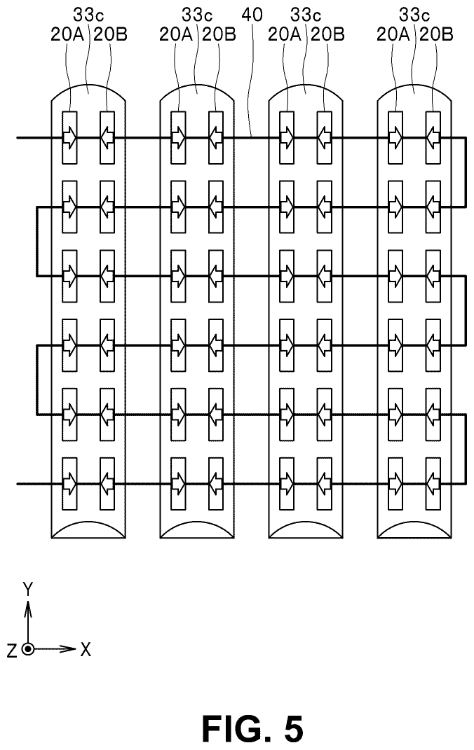

Next, the arrangement of the plurality of first MR elements 20A and the plurality of second MR elements 20B in each of the resistor sections R1 to R4 will be described with reference to FIG. 5. FIG. 5 is an explanatory diagram schematically showing any given resistor section of the resistor sections R1 and R3. The plurality of first MR elements 20A and the plurality of second MR elements 20B are disposed so that two or more first MR elements 20A and two or more second MR elements 20B are arranged both in a direction parallel to the X direction and in a direction parallel to the Y direction. Here, a group of the two or more first MR elements 20A arranged in a row along the direction parallel to the Y direction is referred to as a first element array, a group of the two or more second MR elements 20B arranged in a row along the direction parallel to the Y direction is referred to as a second element array. Each of the resistor sections R1 to R4 includes a plurality of first element arrays and a plurality of second element arrays. The plurality of first element arrays and the plurality of second element arrays may be disposed such that the first element arrays and the second element arrays are alternately arranged along the direction parallel to the X direction.

In addition, the two or more first MR elements 20A and the two or more second MR elements 20B may be disposed such that the first MR elements 20A and the second MR elements 20B are alternately arranged along the direction parallel to the X direction. Here, a group of the two or more first MR elements 20A and the two or more second MR elements 20B that are arranged in a row along the direction parallel to the X direction is referred to as a third element array. Each of the resistor sections R1 to R4 includes a plurality of third element arrays. The wiring 40 electrically connects the two or more first MR elements 20A and the two or more second MR elements 20B included in each of the plurality of third element arrays and connects the plurality of third element arrays in series. In each of the resistor sections R1 to R4, the wiring 40 has a meandering shape when viewed in the Z direction.

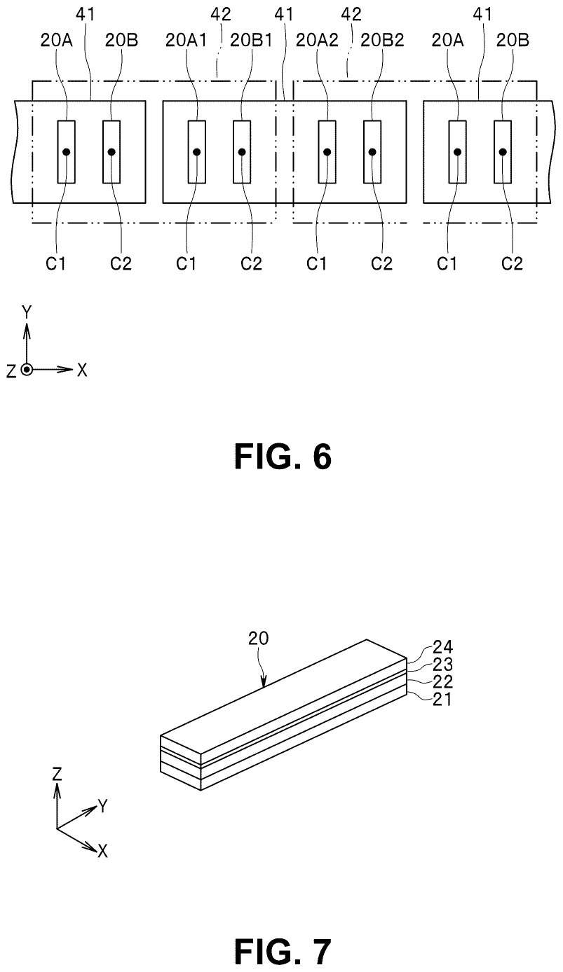

Next, the connecting form of the plurality of first MR elements 20A and the plurality of second MR elements 20B in each of the resistor sections R1 to R4 will be described in detail, with reference to FIG. 4 and FIG. 6. FIG. 6 is a plan view showing the plurality of first MR elements 20A, the plurality of second MR elements 20B, the plurality of lower electrodes 41, and the plurality of upper electrodes 42.

Here, as shown in FIG. 6, the first and second MR elements 20A, 20B, which are disposed respectively on the inclined surfaces 33a, 33b of one of the two adjoining protruding surfaces 33c, are denoted respectively by the reference numerals 20A1, 20B1, and the first and second MR elements 20A, 20B, which are disposed respectively on the inclined surfaces 33a, 33b of the other of the two adjoining protruding surfaces 33c, are denoted respectively by the reference numerals 20A2, 20B2. Each of the plurality of lower electrodes 41 extends along the top surface of the insulating layer 33 in the direction parallel to the X direction, and connects a pair of the first and second MR elements 20A1, 20B1 and a pair of the first and second MR elements 20A2, 20B2.

Each of the plurality of upper electrodes 42 extends along the top surface of the insulating layer 33 in the direction parallel to the X direction, and connects a pair of the first and second MR elements 20A, 20B disposed on one of the two lower electrodes 41 and a pair of the first and second MR elements 20A, 20B disposed on the other of the two lower electrodes 41. The pair of the first and second MR elements 20A1, 20B1 and the pair of the first and second MR elements 20A2, 20B2, which are connected by one lower electrode 41, are connected respectively to different upper electrodes 42. Thus, the plurality of pairs of the first MR elements 20A and the second MR elements 20B are connected in series.

Here, the lower electrode 41 that connects the pair of the first and second MR elements 20A1, 20B1 and the pair of the first and second MR elements 20A2, 20B2 is referred to as a first lower electrode 41. The upper electrode 42 connected to the pair of the first and second MR elements 20A1, 20B1 is referred to as a first upper electrode 42, and the upper electrode 42 connected to the pair of the first and second MR elements 20A2, 20B2 is referred to as a second upper electrode 42. The pair of the first and second MR elements 20A1, 20B1 is disposed between the first lower electrode 41 and the first upper electrode 42, and connected in parallel by the first lower electrode 41 and the first upper electrode 42. The pair of the first and second MR elements 20A2, 20B2 is disposed between the first lower electrode 41 and the second upper electrode 42, and connected in parallel by the first lower electrode 41 and the second upper electrode 42.

The first upper electrode 42 is not directly connected to the pair of the first and second MR elements 20A2, 20B2 disposed on the first lower electrode 41. The second upper electrode 42 is not directly connected to the pair of the first and second MR elements 20A1, 20B1 disposed on the first lower electrode 41. Each of the first upper electrode 42 and the second upper electrode 42 includes a part located above the protruding surface 33c and a part located above the non-protruding surface 33d. An end portion of the first upper electrode 42 in the direction parallel to the X direction and an end portion of the second upper electrode 42 in the direction parallel to the X direction are located above the non-protruding surface 33d located between the two protruding surfaces 33c. In addition, the end portion of the first upper electrode 42 and the end portion of the second upper electrode 42 are disposed above the non-protruding surface 33d spaced apart from each other.

The first lower electrode 41 includes a part located on the protruding surface 33c and a part located on the non-protruding surface 33d. Both end portions of the first lower electrode 41 in the direction parallel to the X direction are located on the non-protruding surface 33d. In addition, the end portion of the first lower electrode 41 in the direction parallel to the X direction is disposed on the non-protruding surface 33d spaced apart from the end portion of another lower electrode 41 in the direction parallel to the X direction.

In FIG. 6, the reference numeral C1 indicates the center of gravity of the first MR element 20A when viewed in the Z direction, and the reference numeral C2 indicates the center of gravity of the second MR element 20B when viewed in the Z direction. The lower electrode 41 and the upper electrode 42 each include a part overlapping with the center of gravity C1 of the first MR element 20A and the center of gravity C2 of the second MR element 20B, when viewed in the Z direction. In the example shown in FIG. 6, in particular, the lower electrode 41 and the upper electrode 42 may each overlap with the entirety of the first MR element 20A and the entirety of the second MR element 20B, when viewed in the Z direction.

As described above, each of the plurality of protruding surfaces 33c extends in the direction parallel to the Y direction. Therefore, each of the inclined surfaces 33a and 33b also extends in the direction parallel to the Y direction. Furthermore, each of the lower electrodes 41 and the upper electrodes 42 extends in the direction parallel to the X direction, when viewed in the Z direction. The dimension of the lower electrode 41 in the direction parallel to the Y direction may be larger than the dimension of the inclined surface 33a in the direction parallel to the X direction and the dimension of the inclined surface 33b in the direction parallel to the X direction. Similarly, the dimension of the upper electrode 42 in the direction parallel to the Y direction may be larger than the dimension of the inclined surface 33a in the direction parallel to the X direction and the dimension of the inclined surface 33b in the direction parallel to the X direction.

The dimension of each of the lower electrodes 41 in the direction parallel to the Y direction may be or may not be constant. Similarly, the dimension of each of the upper electrodes 42 in the direction parallel to the Y direction may be or may not be constant.

Next, a configuration of the MR element 20 will be described with reference to FIG. 7. FIG. 7 is a perspective view showing the MR element 20. The MR element 20 is a spin-valve MR element. The MR element 20 may include a magnetization pinned layer 22, a magnetization direction of the magnetization pinned layer being fixed, a free layer 24, a magnetization direction of the free layer being variable depending on a direction of a magnetic field to be applied, and a gap layer 23 disposed between the magnetization pinned layer 22 and the free layer 24. The MR element 20 may be a tunneling magnetoresistive (TMR) element or a giant magnetoresistive (GMR) element. In the TMR element, the gap layer 23 is a tunnel barrier layer. In the GMR element, the gap layer 23 is a nonmagnetic conductive layer. The resistance of the MR element 20 changes with the angle that the magnetization direction of the free layer 24 forms with respect to the magnetization direction of the magnetization pinned layer 22. The resistance of the MR element 20 is at its minimum value when the foregoing angle is 0°, and at its maximum value when the foregoing angle is 180°.

The MR elements 20 may have a shape that is long in one direction. In the example shown in FIG. 7, the MR element 20 has a shape that is long in the direction parallel to the Y direction. The free layer 24 of each of the MR elements 20 thus has a shape anisotropy such that the direction of the magnetization easy axis is parallel to the Y direction.

The MR element 20 further includes an antiferromagnetic layer 21. The antiferromagnetic layer 21, the magnetization pinned layer 22, the gap layer 23, and the free layer 24 are stacked in this order. The antiferromagnetic layer 21 is formed of an antiferromagnetic material, and is in exchange coupling with the magnetization pinned layer 22 to thereby fix the magnetization direction of the magnetization pinned layer 22. The magnetization pinned layer 22 may be a so-called self-pinned layer (Synthetic Ferri Pinned layer, SFP layer). The self-pinned layer has a stacked ferri structure in which a ferromagnetic layer, a nonmagnetic intermediate layer, and a ferromagnetic layer are stacked, and the two ferromagnetic layers are antiferromagnetically coupled. In a case where the magnetization pinned layer 22 is the self-pinned layer, the antiferromagnetic layer 21 may be omitted.

It should be appreciated that the layers 21 to 24 of each MR element 20 may be disposed in the reverse order to that shown in FIG. 7.

Next, the magnetization directions of the magnetization pinned layers 22 will be described with reference to FIG. 2 and FIG. 4. The direction of the main component of the magnetization of the magnetization pinned layers 22 of the first MR elements 20A in each of the resistor sections R1 and R3 is in the U direction. The direction of the main component of the magnetization of the magnetization pinned layers 22 of the second MR elements 20B in each of the resistor sections R1 and R3 is in the −V direction. The direction of the main component of the magnetization of the magnetization pinned layers 22 of the first MR elements 20A in each of the resistor sections R2 and R4 is in the −U direction. The direction of the main component of the magnetization of the magnetization pinned layers 22 of the second MR elements 20B in each of the resistor sections R2 and R4 is in the V direction.

Note that the magnetization direction of each of the magnetization pinned layers 22 may coincide with the direction of the main component of the magnetization mentioned above, or may deviate slightly from the direction of the main component of

the magnetization. In the description below, referring just to the magnetization direction of each of the magnetization pinned layers 22 indicates the direction of the main component of the magnetization of each of the magnetization pinned layers 22.

In the example embodiment, the inclined surfaces 33a and 33b are curved surfaces. Therefore, the first and second MR elements 20A and 20B are curved respectively along the curved surfaces (the inclined surfaces 33a and 33b). For the sake of convenience, in the example embodiment, the magnetization directions of the magnetization pinned layers 22 of the first and second MR elements 20A, 20B are defined as straight directions as described above. The U direction and the −U direction that are the magnetization directions of the magnetization pinned layers 22 of the first MR elements 20A are also directions in which the tangents to the inclined surfaces 33a at the vicinity of the first MR elements 20A extend. The V direction and the −V direction that are the magnetization directions of the magnetization pinned layers 22 of the second MR elements 20B are also directions in which the tangents to the inclined surfaces 33b at the vicinity of the second MR elements 20B extend.

Here, the magnetization direction of the magnetization pinned layer 22 of each of the first MR elements 20A, when projected perpendicularly on the top surface 31a of the substrate 31, i.e., the reference plane (XY plane), is referred to as a first magnetization direction. The magnetization direction of the magnetization pinned layer 22 of each of the second MR elements 20B, when projected perpendicularly on the top surface 31a of the substrate 31, i.e., the reference plane (XY plane), is referred to as a second magnetization direction. In FIG. 2, the arrows drawn overlapping the first MR elements 20A indicate the first magnetization direction, and the arrows drawn overlapping the second MR elements 20B indicate the second magnetization direction.

In the example embodiment, the first magnetization direction and the second magnetization direction may be opposite to each other. In the example shown in FIG. 2, the first magnetization direction in each of the resistor sections R1 and R3 is in the X direction. The second magnetization direction in each of the resistor sections R1 and R3 is in the −X direction. The first magnetization direction in each of the resistor sections R2 and R4 is in the −X direction. The second magnetization direction in each of the resistor sections R2 and R4 is in the X direction.

Furthermore, the magnetization direction of the magnetization pinned layer 22 of each of the first MR elements 20A, when projected perpendicularly on the YZ plane, is referred to as a third magnetization direction. The magnetization direction of the magnetization pinned layer 22 of each of the second MR elements 20B, when projected perpendicularly on the YZ plane, is referred to as a fourth magnetization direction. The third magnetization direction in each of the resistor sections R1 and R3 and the fourth magnetization direction in each of the resistor sections R1 and R3 are both in the Z direction. The third magnetization direction in each of the resistor sections R2 and R4 and the fourth magnetization direction in each of the resistor sections R2 and R4 are both in the −Z direction.

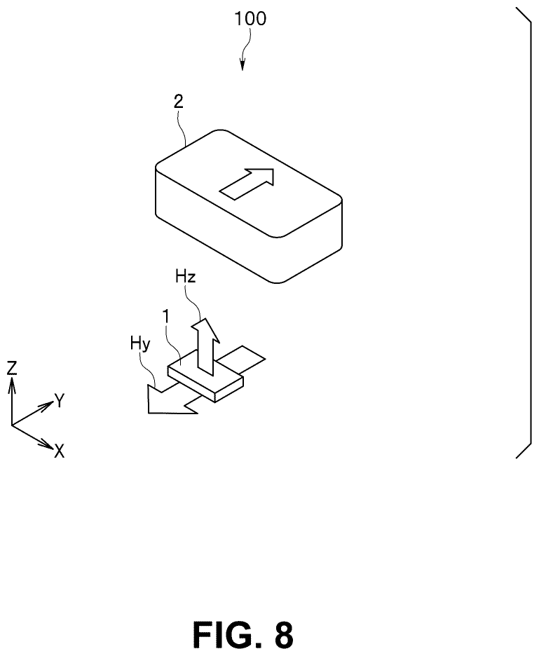

Next, a configuration of a magnetic sensor system 100 including the magnetic sensor 1 will be described with reference to FIG. 8. FIG. 8 is a perspective view showing the magnetic sensor system 100. The magnetic sensor system 100 includes the magnetic sensor 1 and a magnetic field generation section 2 that generates a magnetic field. In the example embodiment, the magnetic field generation section 2 is a magnet configured such that a partial magnetic field, which is a part of the generated magnetic field, is applied to the magnetic sensor 1. This partial magnetic field includes a first magnetic field component Hz parallel to the Z direction and a second magnetic field component Hy parallel to the Y direction.

The magnetization direction of the magnetic field generation section 2 is in the Y direction, and the direction of the second magnetic field component Hy is in the −Y direction. The direction of the first magnetic field component Hz is in the Z direction when the magnetic field generation section 2 moves in the Y direction from a specified position, and is in the −Z direction when the magnetic field generation section 2 moves in the −Y direction from the specified position.

Next, the operation of the magnetic sensor 1 will be described with reference to FIG. 2, FIG. 4, and FIG. 8. The first magnetic field component Hz received by each of the plurality of first MR elements 20A can be separated into a component in a direction parallel to the U direction and a component in a direction orthogonal to the U direction. The first magnetic field component Hz received by each of the plurality of second MR elements 20B can be separated into a component in a direction parallel to the V direction and a component in a direction orthogonal to the V direction.

In a state where there is no first magnetic field component Hz, the magnetization direction of the free layer 24 of each of the plurality of first MR elements 20A and the plurality of second MR elements 20B is in the direction parallel to the Y direction. When the direction of the first magnetic field component Hz is in the Z direction, substantially the magnetic field component in the U direction of the first magnetic field component Hz is applied to each of the plurality of first MR elements 20A, and substantially the magnetic field component in the −V direction of the first magnetic field component Hz is applied to each of the plurality of second MR elements 20B. In this case, the magnetization direction of the free layer 24 of each of the plurality of first MR elements 20A is inclined from the direction parallel to the Y direction to the U direction, and the magnetization direction of the free layer 24 of each of the plurality of second MR elements 20B is inclined from the direction parallel to the Y direction to the −V direction. As a result, the resistance of each of the plurality of first and second MR elements 20A and 20B that constitute the resistor sections R1 and R3 decreases and the resistance of each of the plurality of first and second MR elements 20A and 20B that constitute the resistor sections R2 and R4 increases, as compared to the case where no first magnetic field component Hz exists. As a result, the resistance of each of the resistor sections R1 and R3 decreases and the resistance of each of the resistor sections R2 and R4 increases.

If the direction of the first magnetic field component Hz is in the −Z direction, the direction of the magnetic field component that is applied to each of the plurality of first MR elements 20A, the direction of the magnetic field component that is applied to each of the plurality of second MR elements 20B, and the change in the resistance of each of the resistor sections R1 to R4 are opposite to those in the above-mentioned case where the direction of the first magnetic field component Hz is in the Z direction.

The amount of change in the resistance of each of the resistor sections R1 to R4 depends on the strength of the magnetic field component received by each of the plurality of first MR elements 20A and the plurality of second MR elements 20B. When the strength of the magnetic field component increases, the resistance of each of the resistor sections R1 to R4 changes such that the amount of increase or the amount of decrease of the resistance becomes larger. When the strength of the magnetic field

component decreases, the resistance of each of the resistor sections R1 to R4 changes such that the amount of increase or the amount of decrease of the resistance becomes smaller. The strength of the magnetic field component depends on the strength of the first magnetic field component Hz.

As described above, the changes in the direction and strength of the first magnetic field component Hz cause the resistance of each of the resistor sections R1 to R4 to change either so that the resistance of each of the resistor sections R1 and R3 increases and the resistance of each of the resistor sections R2 and R4 decreases, or so that the resistance of each of the resistor sections R1 and R3 decreases and the resistance of each of the resistor sections R2 and R4 increases. This changes the potential of the connection point between the resistor sections R1 and R2, i.e., the potential of the first output terminal E1, and the potential of the connection point between the resistor sections R3 and R4, i.e., the potential of the second output terminal E2. The magnetic sensor 1 may generate a signal corresponding to the potential of the first output terminal E1 and a signal corresponding to the potential of the second output terminal E2, each as a detection signal. Alternatively, the magnetic sensor 1 may generate a signal corresponding to a potential difference between the first output terminal E1 and the second output terminal E2 as a detection signal. In this case, the magnetic sensor 1 may further include a differential amplifier (difference detector) that outputs the signal corresponding to the potential difference between the first output terminal E1 and the second output terminal E2 as a detection signal.

The magnetic sensor system 100 may further include a processor, not shown. The processor, not shown, may be configured to receive one detection signal or two detection signals output from the magnetic sensor 1 to generate a detection value having a correspondence with the strength of the first magnetic field component Hz or a detection value having a correspondence with the position of the magnetic field generation section 2.

Next, a manufacturing method for the magnetic sensor 1 according to the example embodiment will be briefly described. The manufacturing method for the magnetic sensor 1 includes a step of forming the plurality of first MR elements 20A and the plurality of second MR elements 20B, a step of forming the plurality of lower electrodes 41, a step of forming the plurality of upper electrodes 42, and a step of forming the insulating layers 32 to 37.

The step of forming the plurality of first MR elements 20A and the plurality of second MR elements 20B includes a step of forming a plurality of stacked films which are to later become the plurality of first MR elements 20A and the plurality of second MR elements 20B. Each of the plurality of stacked films includes, at least, an initial magnetization pinned layer which is to later become the magnetization pinned layer 22, and the free layer 24, and the gap layer 23.

The step of forming the plurality of first MR elements 20A and the plurality of second MR elements 20B further includes a fixing step of fixing the magnetization direction of the stacked films by using laser light and the external magnetic field in the specified direction. The fixing step includes a first step and a second step following the first step.

In the first step, the plurality of stacked films are irradiated with the laser light, while applying the external magnetic field in the X direction or in the −X direction to the parts, which is to later become the plurality of first MR elements 20A, of the plurality of stacked films. When the irradiation of the laser light is completed, the magnetization direction of the initial magnetization pinned layers is fixed in the U direction or the −U direction. This makes the initial magnetization pinned layers into the magnetization pinned layers 22, and the plurality of stacked films into the plurality of first MR elements 20A.

After the magnetization of the magnetization pinned layers 22 of the plurality of first MR elements 20A is fixed in the first step, the second step is performed to fix the magnetization of the magnetization pinned layers 22 of the plurality of second MR elements 20B. In the second step, the plurality of stacked films are irradiated with the laser light, while applying the external magnetic field in the X direction or in the −X direction to the parts, which is to later become the plurality of second MR elements 20B, of the plurality of stacked films. When the irradiation of the laser light is completed, the magnetization direction of the initial magnetization pinned layers is fixed in the V direction or the −V direction. This makes the initial magnetization pinned layers into the magnetization pinned layers 22, and the plurality of stacked films into the plurality of second MR elements 20B.

Note that the magnetization of the magnetization pinned layers 22 of the plurality of second MR elements 20B may be fixed in the first step, and the magnetization of the magnetization pinned layers 22 of the plurality of first MR elements 20A may be fixed in the second step. In addition, instead of forming the plurality of stacked films, at least one stacked film may be formed. In such a case, the first step and the second step are performed by using the at least one stacked film. After the first step and the second step are performed, the at least one stacked film is patterned by etching so that the at least one stacked film becomes the plurality of first MR elements 20A and the plurality of second MR elements 20B.

The step of forming the plurality of lower electrodes 41 includes a step of forming a metal film and a step of patterning the metal film by etching so that the metal film becomes the plurality of lower electrodes 41. The step of forming the plurality of upper electrodes 42 includes a step of forming a metal film and a step of patterning the metal film by etching so that the metal film becomes the plurality of upper electrodes 42.

Next, the effects of the magnetic sensor 1 according to the example embodiment will be described. In the example embodiment, the lower electrode 41 and the upper electrode 42 each include the part overlapping with the center of gravity C1 of the first MR element 20A disposed on the inclined surface 33a and the center of gravity C2 of the second MR element 20B disposed on the inclined surface 33b. Now, a case will be considered in which the plurality of first MR elements 20A disposed on the inclined surfaces 33a are connected in series by the plurality of lower electrodes and the plurality of upper electrodes. In such a case, the dimensions of the plurality of lower electrodes and the plurality of upper electrodes in the short-length direction (direction parallel to the X direction) are restricted by the dimension of each of the inclined surfaces 33a in the short-length direction (direction parallel to the X direction). Therefore, in such a case, the dimensions of the plurality of lower electrodes and the plurality of upper electrodes in the short-length direction cannot be made sufficiently large, which has sometimes resulted in the resistance of the wiring 40 not being made sufficiently small.

In contrast, according to the example embodiment, the dimensions of the plurality of lower electrodes 41 and the plurality of upper electrodes 42 in the short-length direction (direction parallel to the Y direction) can be defined without being restricted by the dimension of each of the inclined surfaces 33a and 33b in the short-length direction (direction parallel to the X direction). According to the example embodiment, the resistance of the wiring 40 can be made small. Consequently, according to the example embodiment, the sensitivity of the magnetic sensor 1 can be enhanced.

In addition, in the example embodiment, the plurality of MR elements 20 each have a shape that is long in the direction parallel to the Y direction, and the plurality of lower electrodes 41 and the plurality of upper electrodes 42 each overlap with the entire MR element 20 when viewed in the Z direction. According to the example embodiment, the dimensions of the plurality of lower electrodes 41 and the plurality of upper electrodes 42 in the short-length direction (direction parallel to the Y direction) can be made sufficiently large.

Furthermore, in the example embodiment, the dimensions of the inclined surfaces 33a and 33b in the short-length direction (direction parallel to the X direction) can be made small, without reducing the dimensions of the plurality of lower electrodes 41 and the plurality of upper electrodes 42 in the short-length direction (direction parallel to the Y direction). If a comparison is made supposing that the area of the top surface 31a of the substrate 31 is the same, according to the example embodiment, the number of the MR elements 20 per unit area can be increased, which enables the sensitivity of the magnetic sensor 1 to be enhanced and a resistance to noise of the magnetic sensor 1 to be increased. In addition, if the comparison is made supposing that the number of the MR elements 20 is the same, according to the example embodiment, the size reduction of the magnetic sensor 1 can be achieved.

In the example embodiment, an end portion of one of the two lower electrodes 41 and an end portion of the other of the two lower electrodes 41 are disposed on the non-protruding surface 33d spaced apart from each other. With such a configuration, in the example embodiment, the etching of the metal film which is to later become the plurality of lower electrodes 41 is easier than in the case where the end portion of one of the two lower electrodes 41 and the end portion of the other of the two lower electrodes 41 are located on the protruding surface 33c.

The above description of the lower electrodes 41 also applies to the upper electrodes 42.

### Second Example Embodiment

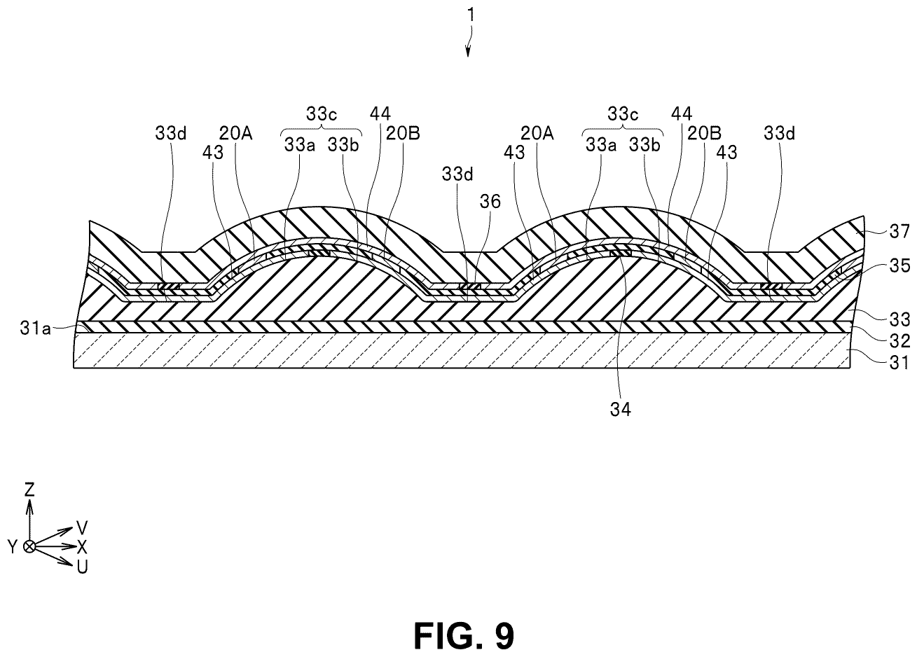

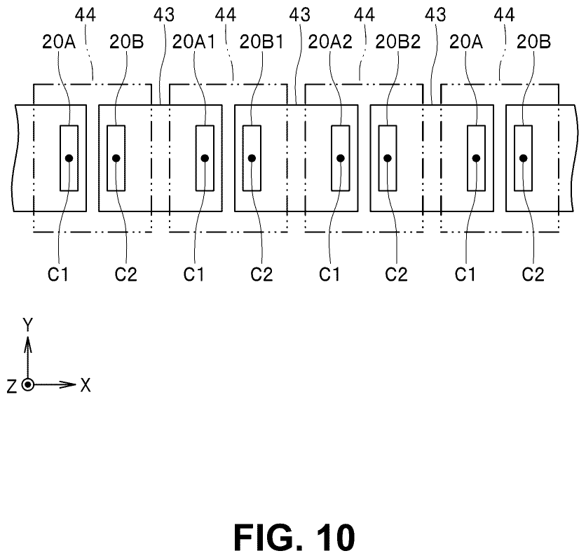

A second example embodiment of the disclosure will now be described with reference to FIG. 9 and FIG. 10. FIG. 9 is a sectional view showing a part of a magnetic sensor according to the example embodiment. FIG. 10 is a plan view showing a part of the magnetic sensor according to the example embodiment.

The following describes how the configuration of the magnetic sensor 1 according to the example embodiment differs from that in the first example embodiment. The magnetic sensor 1 according to the example embodiment includes a plurality of lower electrodes 43 and a plurality of upper electrodes 44, instead of the plurality of lower electrodes 41 and the plurality of upper electrodes 42 in the first example embodiment. In each of the resistor sections R1 to R4 (see FIG. 2), the plurality of first MR elements 20A and the plurality of second MR elements 20B are electrically connected by the plurality of lower electrodes 43 and the plurality of upper electrodes 44.

The plurality of lower electrodes 43 are disposed on the plurality of inclined surfaces 33a and the plurality of inclined surfaces 33b of the insulating layer 33. The insulating layer 34 is disposed around the plurality of lower electrodes 43 on the insulating layer 33. The plurality of first MR elements 20A and the plurality of second MR elements 20B are disposed on the plurality of lower electrodes 43. The insulating layer 35 is disposed around the plurality of first MR elements 20A and around the plurality of second MR elements 20B on the plurality of lower electrodes 43 and the insulating layer 34. The plurality of upper electrodes 44 are disposed on the plurality of first MR elements 20A, the plurality of second MR elements 20B, and the insulating layer 35. The insulating layer 36 is disposed around the plurality of upper electrodes 44 on the insulating layer 35. The insulating layer 37 is disposed on the plurality of upper electrodes 44 and the insulating layer 36.

As shown in FIG. 10, the first and second MR elements 20A and 20B, which are disposed respectively on the inclined surfaces 33a and 33b of one of the two adjoining protruding surfaces 33c are denoted respectively by the reference numerals 20A1 and 20B1, and the first and second MR elements 20A and 20B, which are disposed respectively on the inclined surfaces 33a and 33b of the other of the two adjoining protruding surfaces 33c, are denoted respectively by the reference numerals 20A2 and 20B2. Each of the plurality of lower electrodes 43 extends along the top surface of the insulating layer 33 in the direction parallel to the X direction, and connects the second MR element 20B1 and the first MR element 20A2. Each of the plurality of upper electrodes 44 extends along the top surface of the insulating layer 33 in the direction parallel to the X direction, and connects a pair of the first and second MR elements 20A1 and 20B1 or a pair of the first and second MR elements 20A2 and 20B2. The plurality of first MR elements 20A and the plurality of second MR elements 20B are thus connected in series.

The lower electrode 43 connecting the second MR element 20B1 and the first MR element 20A2 is referred to as a first lower electrode 43, the upper electrode 44 connecting the second MR element 20B1 and the first MR element 20A1 is referred to as a first upper electrode 44, and the upper electrode 44 connecting the first MR element 20A2 and the second MR element 20B2 is referred to as a second upper electrode 44. The second MR element 20B1 is disposed between the first lower electrode 43 and the first upper electrode 44. The first MR element 20A2 is disposed between the first lower electrode 43 and the second upper electrode 44. The first MR element 20A1 is disposed between another lower electrode 43 and the first upper electrode 44. The second MR element 20B2 is disposed between yet another lower electrode 43 and the second upper electrode 44.

The first upper electrode 44 is not directly connected to the first MR element 20A2 disposed on the first lower electrode 43. The second upper electrode 44 is not directly connected to the second MR element 20B1 disposed on the first lower electrode 43. Each of the first upper electrode 44 and the second upper electrode 44 includes a part located above the protruding surface 33c and a part located above the non-protruding surface 33d. An end portion of the first upper electrode 44 in the direction parallel to the X direction and an end portion of the second upper electrode 44 in the direction parallel to the X direction are located above the non-protruding surface 33d located between two protruding surfaces 33c. In addition, the end portion of the first upper electrode 44 and the end portion of the second upper electrode 44 are disposed above the non-protruding surface 33d spaced apart from each other.

The first lower electrode 43 includes a part located on the protruding surface 33c and a part located on the non-protruding surface 33d. Both end portions of the first lower electrode 43 in the direction parallel to the X direction are located respectively on the protruding surfaces 33c. In addition, the end portion of the first lower electrode 43 in the direction parallel to the X direction is disposed spaced apart from the end portion of another lower electrode 43 in the direction parallel to the X direction near the boundary (the upper end portion of the protruding surface 33c) between the inclined surface 33a and the inclined surface 33b on the protruding surface 33c.

The lower electrode 43 and the upper electrode 44 each include a part overlapping with the center of gravity C1 of the first MR element 20A and the center of gravity C2 of the second MR element 20B, when viewed in the Z direction. In the example shown in FIG. 10, in particular, the lower electrodes 43 and the upper electrodes 44 each overlap with the entirety of the first MR element 20A and the entirety of the second MR element 20B, when viewed in the Z direction.

Furthermore, the lower electrode 43 and the upper electrode 44 each extend in the direction parallel to the X direction, when viewed in the Z direction. The dimension of the lower electrode 43 in the direction parallel to the Y direction is larger than the dimension of the inclined surface 33a in the direction parallel to the X direction and the dimension of the inclined surface 33b in the direction parallel to the X direction. Similarly, the dimension of the upper electrode 44 in the direction parallel to the Y direction is larger than the dimension of the inclined surface 33a in the direction parallel to the X direction and the dimension of the inclined surface 33b in the direction parallel to the X direction.

The dimension of each of the lower electrodes 43 in the direction parallel to the Y direction may be or may not be constant. Similarly, the dimension of each of the upper electrodes 44 in the direction parallel to the Y direction may be or may not be constant.

The configuration, operation, and effects of the example embodiment are otherwise the same as those of the first example embodiment.

Note that the disclosure is not limited to the foregoing example embodiments, and various modifications may be made thereto. For example, the shape, arrangement, and number of each of the MR elements 20, the lower electrodes 41, 43, and the upper electrodes 42, 44 are not limited to the examples described in the respective example embodiments and may be optional as long as the requirements set forth in the claims are satisfied. The planar shape (shape viewed in the Z direction) of the MR elements 20 is not limited to the rectangular shape that is long in one direction, but may be an oval shape, an oblong shape, or a polygonal shape that is long in one direction. Alternatively, the planar shape of the MR elements 20 may be a circular or square shape.

In addition, the insulating layer 33 may include a plurality of grooves that are recessed from a flat surface toward the −Z direction. In such a case, each of the plurality of grooves may have two inclined surfaces that are oriented in directions different from each other.

Furthermore, the magnetic sensor of the disclosure may be a part of a geomagnetic sensor that detects geomagnetism. The geomagnetic sensor may include a magnetic sensor configured to detect a magnetic field component in the direction parallel to the X direction and a magnetic sensor configured to detect a magnetic field component in the direction parallel to the Y direction, in addition to the magnetic sensor of the disclosure.

As described above, a magnetic sensor according to one embodiment of the disclosure includes: a support member including a first inclined surface and a second inclined surface that are inclined with respect to a reference plane and oriented in directions different from each other; a first magnetoresistive element disposed on the first inclined surface; a second magnetoresistive element disposed on the second inclined surface; and a first electrode that connects the first magnetoresistive element and the second magnetoresistive element, the first electrode including a part overlapping with a center of gravity of the first magnetoresistive element and a center of gravity of the second magnetoresistive element, when viewed in a first direction perpendicular to the reference plane.

In the magnetic sensor according to one embodiment of the disclosure, each of the first magnetoresistive element and the second magnetoresistive element may include a magnetization pinned layer, a magnetization direction of the magnetization pinned layer being fixed, and a free layer, a magnetization direction of the free layer being variable depending on a magnetic field to be applied. The magnetization direction of the magnetization pinned layer of the first magnetoresistive element, when projected perpendicularly on the reference plane, and the magnetization direction of the magnetization pinned layer of the second magnetoresistive element, when projected perpendicularly on the reference plane, may be opposite to each other.

In addition, in the magnetic sensor according to one embodiment of the disclosure, the first magnetoresistive element and the second magnetoresistive element may be arranged along a second direction parallel to the reference plane. Each of the first magnetoresistive element and the second magnetoresistive element may have a shape that is long in a third direction orthogonal to the second direction and parallel to the reference plane. A dimension of the first electrode in the third direction orthogonal to the second direction and parallel to the reference plane may be larger than a dimension of the first inclined surface in the second direction and a dimension of the second inclined surface in the second direction.

In the magnetic sensor according to one embodiment of the disclosure, the first electrode may overlap with an entirety of the first magnetoresistive element and an entirety of the second magnetoresistive element, when viewed in the first direction.

The magnetic sensor according to one embodiment of the disclosure may further include a third magnetoresistive element, a fourth magnetoresistive element, and a second electrode. The support member may have a first protruding surface and a second protruding surface each protruding in a direction away from the reference plane. The first protruding surface may include a first inclined surface and a second inclined surface. The second protruding surface may include a third inclined surface and a fourth inclined surface that are inclined with respect to the reference plane and oriented in directions different from each other. The third magnetoresistive element may be disposed on the third inclined surface. The fourth magnetoresistive element may be disposed on the fourth inclined surface. The second electrode may connect the third magnetoresistive element and the fourth magnetoresistive element, and include a part overlapping with a center of gravity of the third magnetoresistive element and a center of gravity of the fourth magnetoresistive element, when viewed in the first direction. The first electrode may connect the first magnetoresistive element, the second magnetoresistive element, the third magnetoresistive element, and the fourth magnetoresistive element. The magnetic sensor according to one embodiment of the disclosure may further include a third electrode that connects the first magnetoresistive element and the second magnetoresistive element, the third electrode including a part overlapping with the center of gravity of the first magnetoresistive element and the center of gravity of the second magnetoresistive element, when viewed in the first direction. The second electrode may not be directly connected to the first magnetoresistive element and the second magnetoresistive element. The third electrode may not be directly connected to the third magnetoresistive element and the fourth magnetoresistive element. The support member may further include a non-protruding surface located between the first protruding surface and the second protruding surface. An end portion of the second electrode and an end portion of the third electrode may be disposed above the non-protruding surface spaced apart from each other. The first magnetoresistive element and the second magnetoresistive element may be disposed between the first electrode and the third electrode. The third magnetoresistive element and the fourth magnetoresistive element may be disposed between the first electrode and the second electrode.

When the magnetic sensor according to one embodiment of the disclosure includes the third and fourth magnetoresistive elements and the second electrode, the magnetic sensor of the disclosure may further include a third electrode that connects the second magnetoresistive element and the third magnetoresistive element, the third electrode including a part overlapping with the center of gravity of the second magnetoresistive element and the center of gravity of the third magnetoresistive element, when viewed in the first direction. The support member may further include a non-protruding surface located between the first protruding surface and the second protruding surface. An end portion of the first electrode and an end portion of the second electrode may be disposed above the non-protruding surface spaced apart from each other. The magnetic sensor according to one embodiment of the disclosure may further include a fourth electrode connected to the first magnetoresistive element, the fourth electrode including a part overlapping with the center of gravity of the first magnetoresistive element when viewed in the first direction. An end portion of the third electrode and an end portion of the fourth electrode may be disposed spaced apart from each other near a boundary between the first inclined surface and the second inclined surface. The second magnetoresistive element may be disposed between the first electrode and the third electrode. The third magnetoresistive element may be disposed between the second electrode and the third electrode.

A manufacturing method for the magnetic sensor according to one embodiment of the disclosure includes forming a first magnetoresistive element and a second magnetoresistive element. Each of the first magnetoresistive element and the second magnetoresistive element includes a magnetization pinned layer, a magnetization direction of the magnetization pinned layer being fixed, and a free layer, a magnetization direction of the free layer being variable depending on a magnetic field to be applied. The forming the first magnetoresistive element and the second magnetoresistive element includes: forming a stacked film including an initial magnetization pinned layer, which is to later become the magnetization pinned layer, and the free layer; and fixing a magnetization direction of the initial magnetization pinned layer by using laser light and an external magnetic field. The fixing includes a first step of fixing the magnetization direction of the initial magnetization pinned layer in a part, which is to later become the first magnetoresistive element, of the stacked film, and includes, after the first step, a second step of fixing the magnetization direction of the initial magnetization pinned layer in a part, which is to later become the second magnetoresistive element, of the stacked film.

In the magnetic sensor of the disclosure, the first electrode includes the part overlapping with the center of gravity of the first magnetoresistive element disposed on the first inclined surface and the center of gravity of the second magnetoresistive element disposed on the second inclined surface. According to the disclosure, the resistance of the wiring that connects the magnetoresistive elements can thus be reduced.

It is apparent that the disclosure can be carried out in various forms and modification examples in the light of the foregoing descriptions. Accordingly, within the scope of the following claims and equivalents thereof, the disclosure can be carried out in forms other than the foregoing example embodiments.

What is claimed is:

1. A magnetic sensor comprising:
a support member including a first inclined surface and a second inclined surface that are inclined with respect to a reference plane and oriented in directions different from each other;
a first magnetoresistive element disposed on the first inclined surface;
a second magnetoresistive element disposed on the second inclined surface; and
a first electrode that connects the first magnetoresistive element and the second magnetoresistive element, the first electrode including a part overlapping with a center of gravity of the first magnetoresistive element and a center of gravity of the second magnetoresistive element, when viewed in a first direction perpendicular to the reference plane.

2. The magnetic sensor according to claim 1, wherein
each of the first magnetoresistive element and the second magnetoresistive element includes a magnetization pinned layer, a magnetization direction of the magnetization pinned layer being fixed, and a free layer, a magnetization direction of the free layer being variable depending on a magnetic field to be applied, and
the magnetization direction of the magnetization pinned layer of the first magnetoresistive element, when projected perpendicularly on the reference plane, and the magnetization direction of the magnetization pinned layer of the second magnetoresistive element, when projected perpendicularly on the reference plane, are opposite to each other.

3. The magnetic sensor according to claim 1, wherein
the first magnetoresistive element and the second magnetoresistive element are arranged along a second direction parallel to the reference plane, and
each of the first magnetoresistive element and the second magnetoresistive element has a shape that is long in a third direction orthogonal to the second direction and parallel to the reference plane.

4. The magnetic sensor according to claim 1, wherein
the first magnetoresistive element and the second magnetoresistive element are arranged along a second direction parallel to the reference plane, and
a dimension of the first electrode in a third direction orthogonal to the second direction and parallel to the reference plane is larger than a dimension of the first inclined surface in the second direction and a dimension of the second inclined surface in the second direction.

5. The magnetic sensor according to claim 1, wherein the first electrode overlaps with an entirety of the first magnetoresistive element and an entirety of the second magnetoresistive element, when viewed in the first direction.

6. The magnetic sensor according to claim 1, further comprising:
a third magnetoresistive element;
a fourth magnetoresistive element; and
a second electrode, wherein:
the support member has a first protruding surface and a second protruding surface each protruding in a direction away from the reference plane;
the first protruding surface includes the first inclined surface and the second inclined surface;
the second protruding surface includes a third inclined surface and a fourth inclined surface that are inclined with respect to the reference plane and oriented in directions different from each other;
the third magnetoresistive element is disposed on the third inclined surface;
the fourth magnetoresistive element is disposed on the fourth inclined surface; and
the second electrode connects the third magnetoresistive element and the fourth magnetoresistive element, the second electrode including a part overlapping with a center of gravity of the third magnetoresistive element and a center of gravity of the fourth magnetoresistive element, when viewed in the first direction.

7. The magnetic sensor according to claim 6, wherein the first electrode connects the first magnetoresistive element, the second magnetoresistive element, the third magnetoresistive element, and the fourth magnetoresistive element.

8. The magnetic sensor according to claim 7, further comprising
a third electrode that connects the first magnetoresistive element and the second magnetoresistive element, the third electrode including a part overlapping with the center of gravity of the first magnetoresistive element and the center of gravity of the second magnetoresistive element, when viewed in the first direction, wherein
the second electrode is not directly connected to the first magnetoresistive element and the second magnetoresistive element, and
the third electrode is not directly connected to the third magnetoresistive element and the fourth magnetoresistive element.

9. The magnetic sensor according to claim 8, wherein
the support member further includes a non-protruding surface located between the first protruding surface and the second protruding surface, and
an end portion of the second electrode and an end portion of the third electrode are disposed above the non-protruding surface spaced apart from each other.

10. The magnetic sensor according to claim 8, wherein
the first magnetoresistive element and the second magnetoresistive element are disposed between the first electrode and the third electrode, and
the third magnetoresistive element and the fourth magnetoresistive element are disposed between the first electrode and the second electrode.

11. The magnetic sensor according to claim 6, further comprising a third electrode that connects the second magnetoresistive element and the third magnetoresistive element, the third electrode including a part overlapping with the center of gravity of the second magnetoresistive element and the center of gravity of the third magnetoresistive element, when viewed in the first direction.

12. The magnetic sensor according to claim 11, wherein
the support member further includes a non-protruding surface located between the first protruding surface and the second protruding surface, and
an end portion of the first electrode and an end portion of the second electrode are disposed above the non-protruding surface spaced apart from each other.

13. The magnetic sensor according to claim 11, further comprising a fourth electrode connected to the first magnetoresistive element, the fourth electrode including a part overlapping with the center of gravity of the first magnetoresistive element, when viewed in the first direction.

14. The magnetic sensor according to claim 13, wherein an end portion of the third electrode and an end portion of the fourth electrode are disposed spaced apart from each other near a boundary between the first inclined surface and the second inclined surface.

15. The magnetic sensor according to claim 11, wherein
the second magnetoresistive element is disposed between the first electrode and the third electrode, and
the third magnetoresistive element is disposed between the second electrode and the third electrode.

16. A manufacturing method for the magnetic sensor according to claim 1,
the manufacturing method comprising forming the first magnetoresistive element and the second magnetoresistive element, wherein
each of the first magnetoresistive element and the second magnetoresistive element includes a magnetization pinned layer, a magnetization direction of the magnetization pinned layer being fixed, and a free layer, a magnetization direction of the free layer being variable depending on a magnetic field to be applied,
the forming the first magnetoresistive element and the second magnetoresistive element includes:
forming a stacked film including an initial magnetization pinned layer, which is to later become the magnetization pinned layer, and the free layer; and
fixing a magnetization direction of the initial magnetization pinned layer by using laser light and an external magnetic field, and
the fixing includes a first step of fixing the magnetization direction of the initial magnetization pinned layer in a part, which is to later become the first magnetoresistive element, of the stacked film, and includes, after the first step, a second step of fixing the magnetization direction of the initial magnetization pinned layer in a part, which is to later become the second magnetoresistive element, of the stacked film.
